(19) United States
(12) Patent Application Publication
(10) Pub. No.: US 2006/0157725 A1
(43) Pub. Date: Jul. 20, 2006

(54) LED assembly having overmolded lens on treated leadframe and method therefor

(75) Inventor: Edward M. Flaherty, New Milford, CT (US)

Correspondence Address: Robert V. Vickers, Esq.;Fay, Sharpe, Fagan, Minnich & McKee, LLP, Seventh Floor, 1100 Superior Avenue, Cleveland, OH, 44114-2579, US

(73) Assignee: Barnes Group, Inc.

(21) Appl. No.: 11/333,932

(22) Filed: Jan. 18, 2006

Related U.S. Application Data
(60) Provisional application No. 60/645,321, filed on Jan. 20, 2005.

(51) Int. Cl. H01L 33/00

(52) U.S. Cl. 257/99

(57) ABSTRACT

An LED assembly is manufactured by providing a base on a leadframe, installing an LED within the base, and treating the leadframe with the base thereon to prepare for overmolding. A cover is overmolded onto the leadframe with the base thereon to encapsulate the LED.

### CROSS-REFERENCE TO RELATED APPLICATIONS

This application claims the benefit of U.S. Provisional Application No. 60/645,321 filed Jan. 20, 2005, which is expressly incorporated herein by reference.

### BACKGROUND

The present disclosure relates to light emitting diode (LED) technology and, more particularly, to an LED assembly having an overmolded cover or lens on a treated leadframe and a method of manufacturing said LED assembly. In one embodiment, the LED assembly and method employs a liquid silicone rubber (LSR) material to form the overmolded lens and a cold plasma treatment to treat the leadframe prior to overmolding the lens thereon and will be described with particular reference thereto. However, it is to be appreciated that the LED assembly and method described herein may have utility in a variety of other similar environments and applications.

An LED assembly generally includes a base, an LED supported by the base and a cover over the LED. The LED is typically a piece of semiconductor material having wire leads extending therefrom for delivering current to the LED. The cover is typically a substantially transparent material having a dome-shape and acting as a lens for light emitted from the LED. When assembled, the cover and base serve to encapsulate the LED and protect it from adverse environmental effects. The optically transmissive cover additionally serves to enhance light emission from the LED and control external radiation patterns from the LED.

To manufacture the LED assembly, a continuous strip of leadframe material is provided. The leadframe material includes defined contact areas around each of which a base is disposed. The base includes a recess in an upper surface thereof and a support surface defined within the recess. Often the base can additionally include an annular lens retaining recess defined annularly within the base recess. The continuous leadframe strip with bases supported thereon about its contact areas is moved along an assembly line and, at a designated station, has an LED die installed on each base. More specifically, the LED die is attached to the base and wires extending from the LED die are bonded to the leadframe.

The open-ended base on the leadframe with the LED mounted therein is sometimes referred to as an open package. The open package is further moved along the assembly line and a lens is secured to the base to encapsulate the LED. More specifically, the lens, which has a dome shape and an annular mounting portion, is secured to the base over the LED via a snap-fit. When employed, an annular mounting portion of the cover is received within the annular lens retaining recess of the base to secure the lens to the base.

### SUMMARY

In accordance with one aspect, a method of manufacturing an LED assembly is provided. More particularly, in accordance with this aspect, a base is provided on a leadframe. An LED is installed within the base. The leadframe with the base thereon is treated to prepare for overmolding of a lens. After treatment and LED installation, the lens is overmolded onto the leadframe with the base thereon to encapsulate the LED.

In accordance with another aspect, a method of manufacturing an LED assembly is provided. More particularly, in accordance with this aspect, a base is overmolded onto a leadframe. An LED is installed onto the base. At least one of the base and the leadframe is surface treated. A lens is overmolded onto said at least one of the base and the leadframe to encapsulate the LED.

In accordance with yet another aspect, a method of manufacturing a plurality of LED assemblies is provided. More particularly, in accordance with this aspect, a continuous leadframe having a plurality of contact areas is provided. An open package is formed around each of the plurality of contact areas by overmolding a base around each of the contact areas and attaching an LED die to the leadframe. The open package is cold plasma treated. A lens is overmolded onto the open package to form an LED assembly.

In accordance with still another aspect, a method of manufacturing LED assemblies is provided. More particularly, in accordance with this aspect, an overmolded leadframe is provided. An LED die is attached to the overmolded leadframe. The overmolded leadframe with the LED die mounted thereto is surface treated to prepare the overmolded leadframe for a subsequent step of encapsulating the LED die.

In accordance with still yet another aspect, a method of manufacturing LED assemblies is provided. More particularly, in accordance with this aspect, a leadframe having a plurality of base members secured thereto is provided. An LED is mounted to each of the bases. The LED is wire bonded to the leadframe. The leadframe with the LED mounted and bonded thereto is surface treated. A cover is overmolded onto the leadframe over the LED.

In accordance with another aspect, an LED assembly is provided. More particularly, in accordance with this aspect, the LED assembly includes a base on a leadframe. An LED is supported by the base and electrically connected the leadframe. A lens is overmolded onto at least one of the base and the leadframe to encapsulate the LED. The said at least one of the base and the leadframe is cold plasma treated to allow the lens to be bonded thereto.

### BRIEF DESCRIPTION OF THE DRAWINGS

FIG. 1 is a prior art schematic cross-sectional view of a continuous leadframe having bases thereon.

FIG. 2 is a prior art schematic cross-sectional view of the leadframe of FIG. 1 showing an LED die being installed within each of the bases to form open packages.

FIG. 3 is a prior art schematic cross-sectional view of the leadframe of FIG. 2 showing a cover being installed on each of the open packages.

FIG. 4 is a schematic cross-sectional view of a continuous leadframe having bases overmolded thereon.

FIG. 5 is a schematic cross-sectional view of the leadframe of FIG. 4 showing an LED die being installed within each of the bases to form open packages.

FIG. 6 is a schematic cross-sectional view of the leadframe of FIG. 5 showing a surface treatment being applied to the open packages.

FIG. 7 is a schematic cross-sectional view of the leadframe of FIG. 6 showing a cover being overmolded onto each of the open packages.

FIG. 8 is a schematic cross-sectional view of an LED assembly.

FIG. 9 is a graphical representation of surface energy of the leadframe after undergoing a surface treatment versus time.

### DETAILED DESCRIPTION

With reference to FIG. 1, a continuous leadframe 10 includes a plurality of bases 12. Each base 12 is generally formed of a thermoset or thermoplastic material and is overmolded on the leadframe 10 at desired locations. Each base includes a recess 14 defined in an upper side 16 thereof. A support surface 18 defines an inward end of the recess 14. Support surface 18 and tapered cylindrical wall 20, which defines a radial boundary of the support surface 18, together define an LED receiving area 22. Spaced outwardly in the recess 14 relative to the support surface 18 is an annular retaining recess 26 defined in a cylindrical wall section 28. As will be described in more detail below, the recess 26 and the wall section 28 together form a structure for securely receiving a cover.

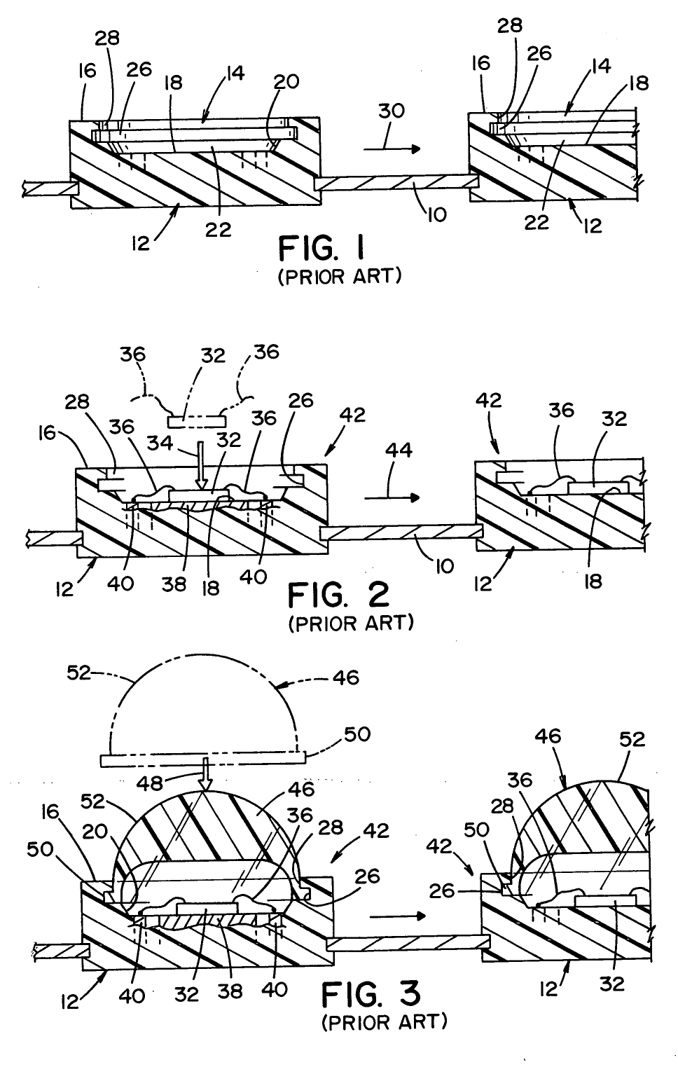

The leadframe 10 with the bases 12 thereon can be advanced in the direction of the arrow 30 toward a station or location wherein an LED die is installed in each base. More particularly, with reference to FIG. 2, LED die 32 is installed in the base 12 as indicated by arrow 34. Specifically, the LED die 32 is positioned on the support surface 18 and wires 36 of the die 32 are bonded to the leadframe 10. In the illustrated embodiment, the support surface 18 can be an exposed area of the leadframe 10 indicated as contact area 38. The LED die 32 is positioned or placed on the contact area 38 and the LED wires 36 are wire bonded to adjacent portions 40 of the leadframe 10 as will be understood by those skilled in the art.

With the LED die 32 installed within, into or on the base 12, an open package is formed and generally indicated by reference numeral 42. The open package 42 can be further advanced as indicated by arrow 44 to a cover installing location or station. With reference to FIG. 3, the open package 42 can have a cover 46 snap fit to the base 12 for encapsulating the LED die 32 and the bonded wires 36 as indicated by arrow 48. Specifically, an annular support ring portion 50 of the cover 46 is received (i.e., snap fit) within the annular lens retaining recess 26 of the base 12. A dome portion 52 of the cover is partially received in the recess 14 adjacent the cylindrical wall section 28.

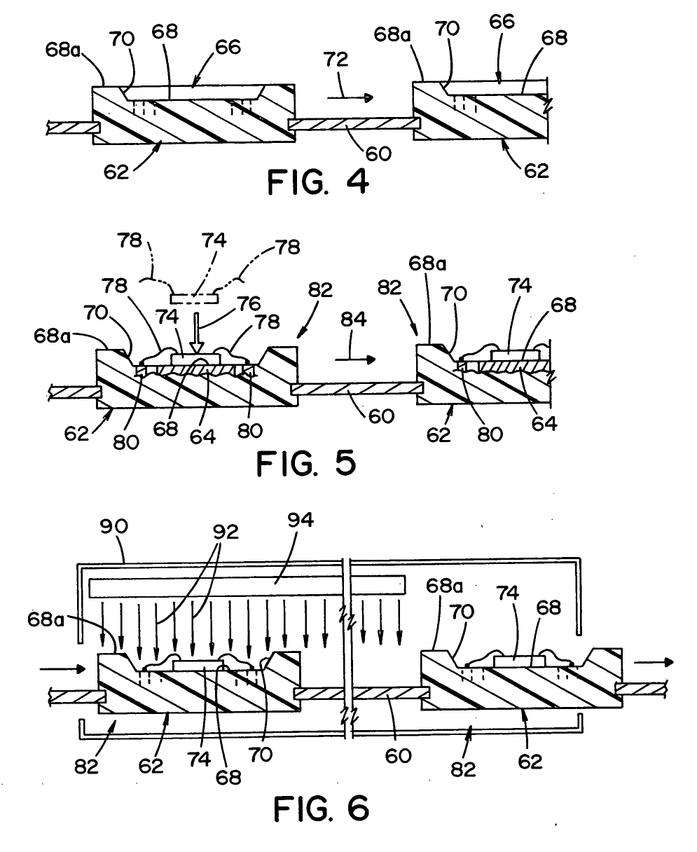

With reference to FIGS. 4-8, an improved method of manufacturing an LED assembly according to one embodiment will be described. With specific reference to FIG. 4, a continuous leadframe 60 having a plurality of bases 62 thereon is provided. More particularly, in one embodiment, each base 62 is overmolded onto the leadframe about a contact area 64 (FIG. 5) of the leadframe. Specifically, the base 62 is overmolded onto the leadframe 60 around the contact area 64. The base 62 includes a recess 66 providing access to the contact area 64. The recess 66 is defined by a support surface 68 (which is a top surface of the contact area 64 in the illustrated embodiment) and a tapered cylindrical wall 70 of the base 62 defined in surface 68a.

To further process the leadframe 60 with bases 62 secured thereto, the leadframe is advanced in the direction of arrow 72 to a station or location for having an LED die installed. With reference to FIG. 5, each base 62 overmolded on the leadframe 60 has an LED die 74 installed within the base. Installing the LED die 74 includes the step of mounting the LED 74 onto the base 62 as indicated by arrow 76 and bonding wires 78 of the die 74 to the leadframe 60. Specifically, the LED die 74 is mounted or attached to the support surface 68 and the wires 78 are bonded to adjacent contact portions 80 of the leadframe 60. The support surface 68 can be formed of the base 62, the contact area 64 of the leadframe 60, or some combination thereof.

Generally, a die attach and wire bonder assembly (not shown) is used to attach the LED 74 to the base 62 and electrically connect the wire 78 of the LED 74 to the leadframe 60. Alternatively, the step of installing the LED 74 within the base 62 can be accomplished by using a ball grid array assembly (BGA) (not shown) which surface mounts the LED 74 onto the base 62 and connects the wires or leads 78 of the LED 74 to the leadframe 60. BGA assemblies and die attach and wire bonder assemblies are well known to those skilled in the art and need not be described in further detail herein. With the LED 74 installed, an open package 82 is formed by the combination of the leadframe 60, the base 62 and the mounted and electrically connected LED 74. The open package 82 can then be moved along the assembly line as indicated by arrow 84 for further processing as will be described below.

Each open package 82 comprising of the leadframe 60, the base 62 and the LED 74 is next treated for preparation of overmolding. In the illustrated embodiment, the open package 82 is moved through a tunnel 90 wherein a treatment is applied to the open package 82 as indicated by the arrows 92. In the illustrated embodiment, the treatment is a surface treatment that includes plasma treating the leadframe 60 with the base 62 thereon, and with the LED 74 on the base 62. Plasma treating, as will be known and appreciated by those skilled in the art, involves blasting the leadframe 60 with the bases 62 thereon (and with LEDs 74 on the bases 62 in the illustrated embodiment) with a stream of high energy ions, atoms, molecules and electrons to remove at least a thin layer of surface contaminants from at least the leadframe 60 and the base 62. Thus, in the illustrated embodiment, a plasma generator 94 directs such a stream as indicated by arrows 92 toward the open package 82 within the tunnel 90. One example of a plasma generator suitable for use in the illustrated embodiment is disclosed in U.S. Pat. No. 6,764,658 assigned to Wisconsin Alumni Research Foundation, and herein expressly incorporated by reference.

In an alternate embodiment, an interfacial bonding material is applied to the open package 82 to prepare the leadframe 60 with the base 62 thereon (and the LED 74 on the base 62 in the illustrated embodiment) for a subsequent step of overmolding. The alternate embodiment employing the application of interfacial bonding material can be used instead of the cold plasma treatment described above. In either case (with cold plasma treatment or application of interfacial bonding), as will be described in more detail below, the surface treatment has the effect of increasing the surface energy on at least one of a leadframe 60 and the base 62. Increasing the surface energy of a surface prepares the surface for cohering to another applied surface. Although not shown, in one alternate embodiment the leadframe 60 and base 62 can be treated prior to the step of installing the LED 74.

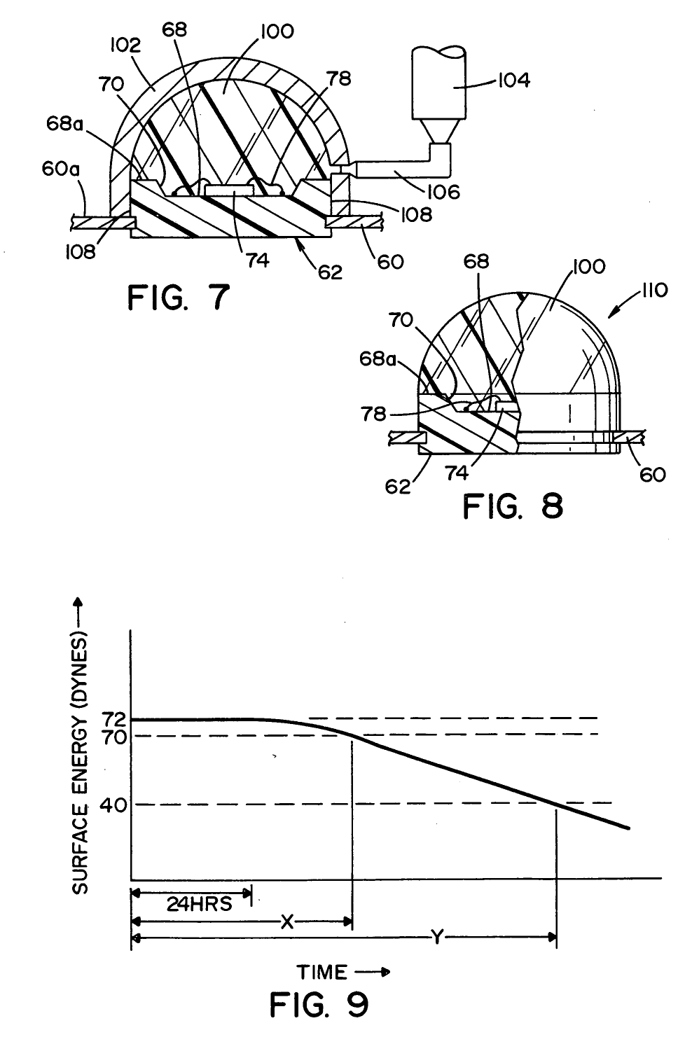

With reference to FIG. 7, the surface treated open package next has a cover 100 overmolded thereon to encapsulate the LED 74. More specifically, the cover 100 is overmolded onto the leadframe 60 with the base 62 thereon to hermetically seal the LED 74 between the base 62 and the overmolded cover 100. In one embodiment, a liquid silicone rubber (LSR) material is used to overmold the cover 100 onto the open package 82. In particular, the open package is moved into position within a dome-shaped mold 102. Molder 104, such as an injection molder, compression molder or the like, delivers a viscous material, such as liquid silicone rubber, through a runner section 106 and into the mold 102 to form the cover 100.

The molding of the cover 100 occurs under low pressure and includes the step of forming a lens over the LED. More particularly, the liquid silicone rubber material not only covers the LED but provides an optically transmissive surface thereover. The overmolded viscous material cools/cures to form a molded cover on the open package. In the illustrated embodiment, the cover/lens 100 bonds to the base 62 and any exposed content area 68 of the leadframe, both of the open package 82, and more particularly to surfaces 68, 68a and 70 of the open package 82. Alternatively, the mold 102 could be configured to mold the cover 100 around the base 62 wherein the cover would bond to sidewalls 108 of the base and a top surface 60a of the leadframe 60. The increased surface energy caused by the surface treatment improves the bonding ability of the molded material with the leadframe and the base. Thus, the lens 100 is securely bonded to the open package 82.

With reference to FIG. 8, the method or process described above ultimately forms an LED assembly 110. The LED assembly 110 includes the base 62 on a portion of the leadframe 60 and an LED 74 supported by the base and electrically connected to the leadframe via wires 78. The cover 100 as described above, is overmolded onto the base 62 to encapsulate the LED 74.

With reference to FIG. 9, cold plasma treatment of surfaces of the leadframe and/or the base as described herein causes increased surface energy in the treated surfaces which lasts for a substantial period of time. In one embodiment, the surface energy of the base 62 after cold plasma treatment increases and remains at approximately 72 dynes/cm (mN/m) for greater than twenty-four hours. This is the most preferred period in which to overmold the base 62 with the LSR cover 100 to encapsulate the LED 74 as the cover 100 will from a very strong bond with the base 62. After cold plasma treatment, the surface energy of the base 62 remains above 70 dynes/cm (mN/m) for a duration of X, which has been found to be about 72 hours. This is still a preferred period in which to overmold the base 62 as a strong bond can still be formed between the cover 100 and the base 62. The surface energy of the base 62 remains above 40 dynes/cm (mN/m) for a duration of Y, which has been found to be about twelve (12) weeks or more. After period Y expires, the surface energy of the base 62 returns to a nominal value of below 40 dynes/cm (mN/m) and generally remains between about 20 dynes/cm (mN/m) and 40 dynes/cm (mN/m). After period X expires, overmolding of the lens 100 is still improved during the remainder of period Y.

The exemplary embodiment has been described with reference to the embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

1. A method of manufacturing an LED assembly, comprising:
providing a base on a leadframe;
installing an LED within said base;
treating said leadframe with said base thereon to prepare for overmolding; and
overmolding a cover onto said leadframe with said base thereon to encapsulate said LED.

2. The method of claim 1 wherein said step of providing a base on a leadframe includes:
overmolding said base onto said leadframe.

3. The method of claim 1 wherein said step of providing a base on a leadframe includes:
overmolding said base onto said leadframe around a contact area of said leadframe.

4. The method of claim 1 wherein said step of installing an LED within said base includes:
mounting said LED onto said base; and
bonding wires of said LED to said leadframe.

5. The method of claim 1 wherein said step of installing an LED within said base includes:
using a ball grid array assembly to surface mount said LED onto said base and connect leads of said LED to said leadframe.

6. The method of claim 1 wherein said step of installing an LED within said base includes:
using a die attach and wire bonder assembly to attach said LED to said base and electrically connect wires of said LED to said leadframe.

7. The method of claim 1 wherein said step of treating said leadframe includes:
plasma treating said leadframe with said base thereon.

8. The method of claim 7 wherein said step of plasma treating said leadframe includes:
blasting said leadframe with said base thereon with a stream of at least one of high energy ions, atoms, molecules and electrons to remove at least a thin layer of surface contaminants.

9. The method of claim 1 wherein said step of treating said leadframe includes:
applying an interfacial bonding material to said leadframe with said base thereon to prepare said leadframe with said base thereon for said subsequent step of overmolding said cover.

10. The method of claim 1 wherein said step of overmolding said lens includes:
hermetically sealing said LED between said base and said overmolded cover.

11. The method of claim 1 wherein said step of overmolding said lens includes:
overmolding liquid silicone rubber onto said leadframe with said base thereon under low pressure to encapsulate said LED and form a lens thereover.

12. The method of claim 1 wherein said step of overmolding said lens includes:
bonding said lens onto said leadframe and said base.

13. The method of claim 7 wherein the surface energy of said base increases to about 72 dynes for a period of about 24 hours and said step of overmolding occurs within said period.

14. A method of manufacturing an LED assembly, comprising:
overmolding a base onto a leadframe;
installing an LED onto said base;
surface treating at least one of said base and said leadframe; and
overmolding a lens onto said at least one of said base and said leadframe to encapsulate said LED.

15. The method of claim 14 wherein said step of surface treating includes one of (i) cold plasma treating said at least one of said base and said leadframe and (ii) applying an interfacial bonding material to said at least one of said base and said leadframe.

16. A method of manufacturing a plurality of LED assemblies, comprising:
providing a continuous leadframe having a plurality of contact areas;
forming an open package around each of said plurality of contact areas by overmolding a base around each of said contact areas and attaching an LED die to said leadframe;
cold plasma treating said open package; and
overmolding a lens onto said open package to form an LED assembly.

17. A method of manufacturing LED assemblies, comprising:
providing an overmolded leadframe;
attaching an LED die to said overmolded leadframe; and
surface treating said overmolded leadframe with said LED die mounted thereto to prepare said overmolded leadframe for a subsequent step of encapsulating said LED die.

18. The method of claim 17 further including:
overmolding a lens onto said overmolded leadframe to enclose said LED.

19. A method of manufacturing LED assemblies, comprising:
providing a leadframe having a plurality of base members secured thereto;
mounting an LED to each of said bases;
wire bonding said LED to said leadframe;
surface treating said leadframe with said LED mounted and bonded thereto; and
overmolding a cover onto said leadframe over said LED.

20. An LED assembly, comprising:
a base on a leadframe;
an LED supported by said base and electrically connected to said leadframe; and
a cover overmolded onto at least one of said base and said leadframe to encapsulate said LED, said at least one of said base and said leadframe cold plasma treated to allow said lens to be bonded thereto.
